(19) United States
(12) Patent Application Publication
(10) Pub. No.: US 2006/0249253 A1
(43) Pub. Date: Nov. 9, 2006

(54) Manifold assembly for feeding reactive precursors to substrate processing chambers

(75) Inventors: Ross S. Dando, Nampa, ID (US); Craig M. Carpenter, Boise, ID (US); Garo J. Derderian, Boise, ID (US)

Correspondence Address: WELLS ST. JOHN P.S., 601 W. FIRST AVENUE, SUITE 1300, SPOKANE, WA, 99201, US

(73) Assignee: Micron Technology, Inc., Boise, ID (US)

(21) Appl. No.: 11/481,460

(22) Filed: Jul. 5, 2006

Related U.S. Application Data
(63) Continuation of application No. 10/087,558, filed on Feb. 28, 2002.

(51) Int. Cl. H01L 21/306

(52) U.S. Cl. 156/345.33

(57) ABSTRACT

A reactive precursor feeding manifold assembly includes a body comprising a plenum chamber. A valve is received proximate the body and has at least two inlets and at least one outlet. At least one valve inlet is configured for connection with a reactive precursor source. At least one valve outlet feeds to a precursor inlet to the plenum chamber. A purge stream is included which has a purge inlet to the plenum chamber which is received upstream of the plenum chamber precursor inlet. The body has a plenum chamber outlet configured to connect with a substrate processing chamber. In one implementation, the plenum chamber purge inlet is angled from the plenum chamber precursor inlet. In one implementation, structure is included on the body which is configured to mount the body to a substrate processing chamber with the plenum chamber outlet proximate to and connected with a substrate processing chamber inlet.

### RELATED PATENT DATA

This patent resulted from a continuation application of U.S. patent application Ser. No. 10/087,558 which was filed Feb. 28, 2002.

### TECHNICAL FIELD

This invention relates to apparatus used to feed reactive precursors to substrate processing chambers, for example etching chambers and deposition chambers.

### BACKGROUND OF THE INVENTION

Semiconductor processing in the fabrication of integrated circuitry involves the deposition of layers on semiconductor substrates. Exemplary processes include physical vapor deposition (PVD) and chemical vapor deposition (CVD). In the context of this document, “CVD” includes any process, whether existing or yet-to-be developed, where one or more vaporized chemicals is fed as a deposition precursor for reaction and adherence to a substrate surface. By way of example only, one such CVD process includes atomic layer deposition (ALD). With ALD, successive mono-atomic layers are adsorbed to a substrate and/or reacted with the outer layer on the substrate by successive feeding of different precursors to the substrate surface.

Chemical vapor depositions can be conducted within chambers or reactors which retain a single substrate upon a wafer holder or susceptor. One or more precursor gasses are typically provided to a shower head within the chamber which is intended to uniformly provide the reactant gasses substantially homogeneously over the outer surface of the wafer. The precursors react or otherwise manifest in a deposition of a suitable layer atop the substrate. Plasma enhancement may or may not be utilized and either directly within the chamber or remotely therefrom.

One existing prior art method and structure for providing the precursors to the shower head utilizes a mixing chamber or box which is received over the deposition processor. Precursor feed stream piping extends laterally from sides of the box in elongated feed lines to valving and precursor vaporizers located very remote form the processor chamber. Typically, purge gas lines also communicate with/into the precursor lines remote from the process chamber by suitable valving.

At least with atomic layer deposition, such equipment is not without its associated drawbacks, both in speed of operation and in producing desired ALD layers atop substrates. For example, in a typical ALD operation, single precursors are typically successively provided to the substrate surface, with intermediate purging with inert gas between each precursor feed. The existing method with the above generally described equipment can result in less than adequate purging of the immediately preceding precursor and/or consumption of large amounts of time between each successive precursor feed in order to assure adequate purging.

The invention was motivated in overcoming the above-described drawbacks, although it is in no way so limited. The invention is only limited by the accompanying claims as literally worded without interpretative or other limiting reference to the specification or drawings, and in accordance with the doctrine of equivalents.

### SUMMARY

The invention includes a reactive precursor feeding manifold assembly. In one implementation, such includes a body comprising a plenum chamber. A valve is received proximate the body and has at least two inlets and at least one outlet. At least one valve inlet is configured for connection with a reactive precursor source. At least one valve outlet feeds to a precursor inlet to the plenum chamber. A purge stream is included which has a purge inlet to the plenum chamber which is received upstream of the plenum chamber precursor inlet. The body has a plenum chamber outlet configured to connect with a substrate processing chamber.

In one implementation, a precursor feed stream is included on the body in fluid communication with the plenum chamber at a precursor inlet to the plenum chamber. A purge stream is included on the body in fluid communication with the plenum chamber at a purge inlet to the plenum chamber which is upstream of the plenum chamber precursor inlet and angled from the plenum chamber precursor inlet.

In one implementation, structure is included on the body which is configured to mount the body to a substrate processing chamber with the plenum chamber outlet proximate to and connected with a substrate processing chamber inlet.

Other aspects and implementations are contemplated.

### BRIEF DESCRIPTION OF THE DRAWINGS

Preferred embodiments of the invention are described below with reference to the following accompanying drawings.

FIG. 1 is a diagrammatic illustration of a preferred embodiment implementation of the invention.

FIG. 2 is a perspective view a preferred embodiment reduction-to-practice structure.

FIG. 3 is a reduced scale diagrammatic illustration of the FIG. 1 diagrammatic embodiment connected with a deposition chamber.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

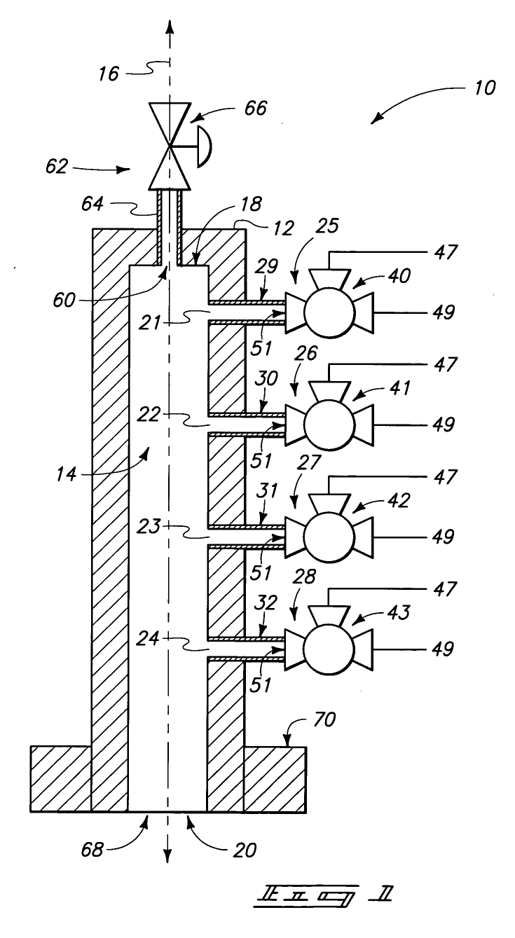

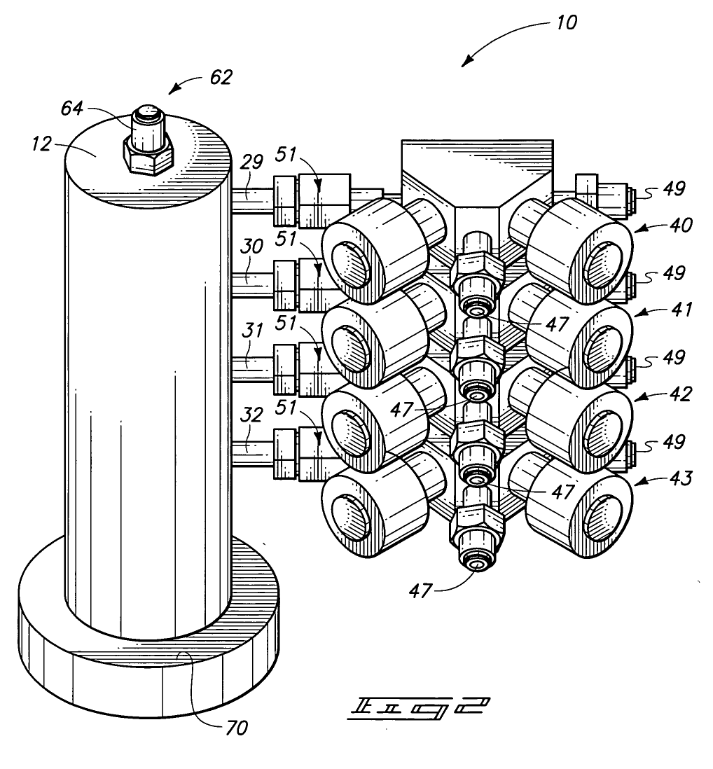

The invention encompasses a manifold assembly 10 for use in feeding reactive precursors to existing or yet-to-be developed substrate processing chambers. Exemplary such chambers include CVD chambers (including ALD) and etching chambers. In the context of this document, a “reactive precursor” is any substance which reacts with another precursor within the chamber or with something/anything else in the chamber. Referring initially to FIGS. 1 and 2, a preferred embodiment manifold assembly is indicated generally with reference numeral 10. FIG. 1 diagrammatically and conceptually illustrates a preferred embodiment implementation of the invention, with FIG. 2 perspectively showing a preferred exemplary reduction-to-practice structure, and by way of example only. Manifold assembly 10 includes a body 12 having a plenum chamber 14 therein. In the most preferred embodiment, body 12 and plenum chamber 14 are elongated, with plenum chamber 14 having a longitudinal axis 16. For purposes of the continuing discussion, the depicted plenum chamber 14 can be considered as having a first longitudinal axis end 18 and a second longitudinal axis end 20.

Plenum chamber 14 includes at least one precursor inlet. In the depicted preferred embodiment, plenum chamber 14 is depicted as having four precursor inlets 21, 22, 23 and 24 and received along longitudinal axis 16. A plurality of precursor feed streams 25, 26, 27 and 28 are received on body 12 and are in fluid communication with plenum chamber 14 at plenum chamber precursor inlets 21, 22, 23 and 24, respectively. In the depicted preferred embodiment, the respective precursor feed streams include elongated segments 29, 30, 31 and 32, respectively, received within respective openings in body 12. These join with their respective plenum chamber precursor inlets, and are oriented substantially normal to longitudinal axis 16. In the context of this document, “substantially normal” means within 10° of normal.

Preferably, a valve is received in one or more of the precursor feed streams such that it is proximate to the body. In the context of this document, “proximate the body” with respect to a valve means that an outlet of the valve assembly is within 8.0 inches of an external housing surface of the body. FIGS. 1 and 2 depict valves 40, 41, 42 and 43 positioned proximate body 12 in precursor feed streams 25, 26, 27 and 28, respectively. The preferred valves have at least two inlets 47 and 49, and at least one outlet 51. More preferably, the valves are 3-way valves having only two inlets and only one outlet. At least one of the valve inlets is configured for connection with a reactive precursor source, with at least one valve outlet feeding to a precursor inlet to the plenum chamber. The other valve inlet is preferably configured for connection with a purge gas source. Preferably, the valve inlet configured for connection with the purge gas source is upstream of the valve inlet configured for connection with a reactive precursor source. Accordingly, in the most preferred embodiment, valve inlet 47 is configured for connection with a reactive precursor source, and valve inlet 49 is configured for connection with a purge gas source.

Plenum chamber 14 includes a purge gas inlet 60. Such is preferably proximate first end 18 of plenum chamber 14 and upstream of all precursor inlets to plenum chamber 14. In the depicted preferred embodiment, inlet 60 is positioned at end 18. Further preferably, the plenum chamber purge inlet is angled from all precursor inlets to the plenum chamber. In the depicted preferred embodiment, and by way of example only, precursor inlets 21, 22, 23 and 24 are defined by an opening in body 12 joining with an internal face which partially defines plenum chamber 14. Each of these openings are received on a rounded or flat face of plenum chamber 14 and provide but one example wherein no plenum chamber precursor inlet is angled from any other plenum chamber precursor inlet. Plenum chamber purge inlet 60 is received on another body face which partially defines plenum chamber 14, and which is angled at 90° relative to the plenum face upon which inlets 21, 22, 23 and 24 are at least partially defined in the preferred embodiment. Accordingly, plenum chamber purge inlet 60 is angled from plenum chamber precursor inlets 21, 22, 23 and 24 by 90° in the depicted embodiment. Where in the preferred embodiment the purge inlet to the plenum chamber is angled from one or more plenum chamber precursor inlets, such angling is preferably by from about 80° to 100°, and more preferably by from about 89° to 91°. Plenum chamber purge gas inlet 60 is preferably positioned adjacent, and directly on/over, longitudinal axis 16, as shown.

A purge gas stream 62 is provided on manifold assembly body 12 and feeds to purge gas inlet 60. Purge gas stream 62 includes an elongated segment 64 joining with purge gas inlet 60 and which is substantially aligned on longitudinal axis 16. The depicted preferred FIG. 1 embodiment also illustrates an exemplary on/off purge stream valve 66 associated therewith.

Manifold assembly body 12 includes a plenum chamber outlet 68 proximate, and at as shown, second longitudinal end 20. Such is configured to connect with a substrate processing chamber. Such connection might be through elongated piping, by more direct connection with housing or other components of a substrate processing chamber, or by any other manner. The preferred connection embodiment is by a largely direct method, for example whereby structure is provided on the body which is configured to mount the body to a substrate processing chamber with plenum chamber outlet 68 being received proximate to and connected with a substrate processing chamber inlet. One preferred such structure includes a projection from the body, with a particular depicted preferred structure in the manifold assembly 10 embodiment being a flange 70. In one preferred embodiment, the structure is so configured such that longitudinal axis 16 is positioned substantially vertical when mounted to a processor. In the context of this document, “substantially vertical” means within 10° of vertical.

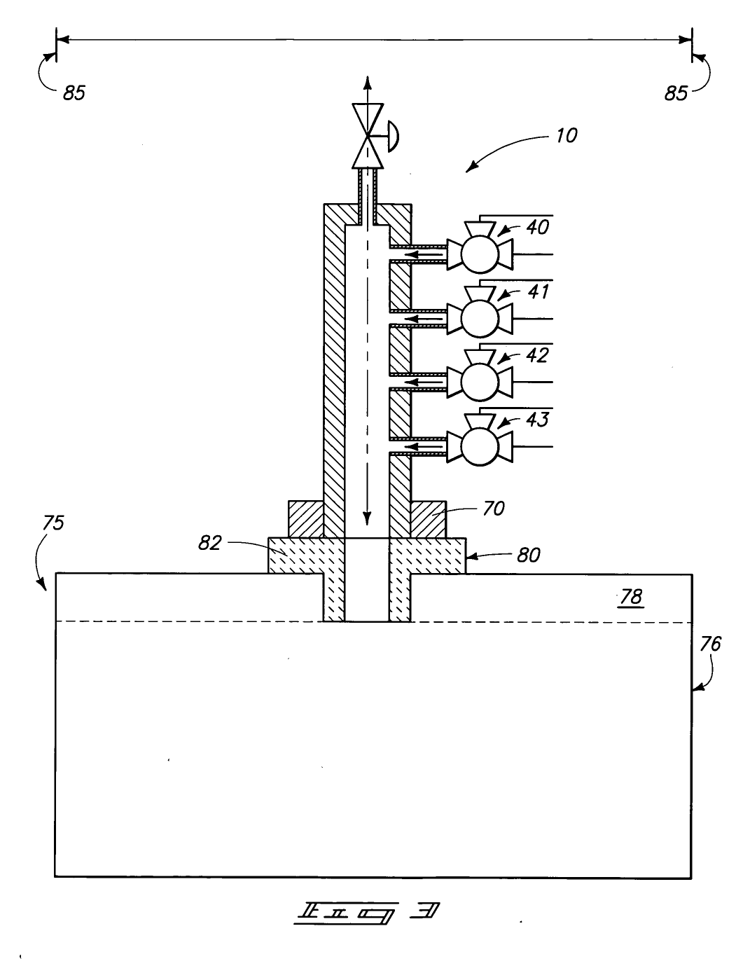

For example, FIG. 3 depicts manifold assembly 10 mounted with a substrate processing chamber 75. Processor 75 can be considered as comprising a chamber housing 76 having a chamber lid 78. An RF insulator adaptor 80 is illustrated intermediate manifold assembly flange 70 and RF chamber lid 78. Such can be utilized to provide RF or other plasma generation source isolation between manifold assembly 10 and chamber 75. Insulator adaptor 80 is depicted as having a flange 82 to which flange 70 can be connected. As the processor or fabricator will appreciate, any desired insulator adaptor can be considered as a separate component from either of processor chamber 75 and manifold assembly 10, or as a component of either.

Chamber housing 76 can be considered as having peripheral lateral confines 85. In the FIG. 3 two-dimensional depiction, only two opposing lateral edges 85 are shown. Of course, third dimension outer lateral edges into and out of the plane of the page upon which FIG. 3 lies would also exist. In one preferred embodiment, one or more of valves 40, 41, 42 and 43, when body 12 is so mounted to a substrate processing chamber, is/are at least partially received within the peripheral lateral confines 85 of chamber housing 76 of substrate processing chamber 75. In the diagrammatic depiction of FIG. 3, valves 40, 41, 42 and 43 are totally received within the peripheral lateral confines 85 of chamber housing 76.

An exemplary preferred material for body 12 and the associated piping is stainless steel. Further by way of example only, the invention was reduced-to-practice using the 3-way valves FBSDV-6.35-2B3-316LP-PA available from Fujikins of Santa Clara, Calif.

In the depicted preferred embodiment, the primary cross-sectional flow path of plenum 14 transverse longitudinal axis 16 is larger than the transverse cross-sectional flow paths of each of precursor openings 21, 22, 23, 24 and segments 29, 30, 31 and 32. Alternately of course, a plenum cross-sectional flow path could be the same or smaller than any one or more of precursor inlets 21, 22, 23 and 24, and/or flow segments 29, 30, 31 and 32.

By way of example only, and in no way of limitation to any claim unless expressly included therein, a preferred manner of atomic layer deposition utilizing the above apparatus would be to flow a single precursor from any of feed streams 47 of a single valve 40, 41, 42 or 43. At the conclusion of the desired precursor feed, such feed is stopped and a purge gas is flowed through the associated valve purge gas stream 49. Simultaneously therewith or subsequent thereto, a purge gas is caused to flow through plenum chamber purge inlet 60. Such can advantageously provide or create a venturi effect to facilitate drawing of any precursor from segments 29, 30, 31 and 32 downstream of the valve mechanism to purge precursor therefrom. Subsequently, another precursor can be flowed from the same or another valve. Such can also facilitate deposited film uniformity across the substrate surface by providing a more uniform symmetrical gas flow of desired composition into the chamber.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A reactive precursor feeding manifold assembly, comprising:
a body comprising a plenum chamber;
a first valve proximate the body, the first valve being a multi-inlet valve having at least two inlets and at least one outlet, a first inlet of the first valve being configured for connection with a reactive precursor source, at least one valve outlet feeding to a precursor inlet to the plenum chamber, the first valve being the only valve associated with the precursor inlet;
a second valve associated with a purge gas stream having a purge gas inlet to the plenum chamber received upstream of the plenum chamber precursor inlet, the second valve being a single-inlet valve having a single inlet and a single outlet; and
the body comprising a plenum chamber outlet configured to connect with a substrate processing chamber.

2. The manifold assembly of claim 1 comprising a plurality of multi-inlet valves having respective precursor inlets to the plenum chamber, the plenum chamber purge gas stream inlet being upstream of all precursor inlets to the plenum chamber.

3. The manifold assembly of claim 1 wherein the first valve has only two inlets and only one outlet.

4. The manifold assembly of claim 1 wherein the first valve has only two inlets and only one outlet, a second inlet of the first valve being configured for connection with a purge gas line.

5. The manifold assembly of claim 4 wherein the second inlet of the first valve is upstream of the first inlet of the first valve.

6. The manifold assembly of claim 4 comprising a plurality of multi-inlet valves and having respective precursor inlets to the plenum chamber, the plenum chamber purge gas stream inlet being upstream of all precursor inlets to the plenum chamber.

7. The manifold assembly of claim 1 further comprising structure on the body configured to mount the body to a substrate processing chamber with the plenum chamber outlet proximate to and connected with a substrate processing chamber inlet.

8. The manifold assembly of claim 1 further comprising structure on the body configured to mount the body to a substrate processing chamber with the plenum chamber outlet proximate to and connected with a substrate processing chamber inlet, the first valve when the body is so mounted being at least partially received within peripheral lateral confines of a chamber housing of the substrate processing chamber.

9. The manifold assembly of claim 8 wherein the first_valve when the body is so mounted is totally received within peripheral lateral confines of said chamber housing.

10. The manifold assembly of claim 1 comprising:
a plurality of multi-inlet valves having respective precursor inlets to the plenum chamber, the plenum chamber purge gas stream inlet being upstream of all precursor inlets to the plenum chamber;
structure on the body configured to mount the body to a substrate processing chamber with the plenum chamber outlet proximate to and connected with a substrate processing chamber inlet, the respective multi-inlet valves when the body is so mounted being at least partially received within peripheral lateral confines of a chamber housing of the substrate processing chamber.

11. The manifold assembly of claim 10 wherein the multi-inlet valves when the body is so mounted are totally received within peripheral lateral confines of said chamber housing.

12. The manifold assembly of claim 1 wherein the plenum chamber is longitudinally elongated having a longitudinal axis, the plenum chamber having a first longitudinal axis end and a second longitudinal axis end, the plenum chamber purge gas inlet being proximate the first end, the plenum chamber outlet being proximate the second end.

13. The manifold assembly of claim 12 wherein the plenum chamber purge gas inlet is on the longitudinal axis.

14. A reactive precursor feeding manifold assembly, comprising:
a body comprising a plenum chamber, the plenum chamber being longitudinally elongated having a longitudinal axis, the plenum chamber having a first end and a second end, the first end being disposed at a first endpoint of the longitudinal axis and a the second end being disposed at an opposing second endpoint of the longitudinal axis;
a plurality of respective precursor feed streams on the body in fluid communication with the plenum chamber at respective precursor inlets to the plenum chamber;
a purge gas stream on the body in fluid communication with the plenum chamber at a purge gas inlet to the plenum chamber which is upstream of all precursor inlets to the plenum chamber, the plenum chamber purge gas inlet being proximate the first end and being angled from all precursor inlets to the plenum chamber; and
the body comprising a plenum chamber outlet configured to connect with a substrate processing chamber, the plenum chamber outlet being proximate the second end, the longitudinal axis of the plenum chamber being substantially vertical when the plenum chamber outlet is connected with the substrate processing chamber.

15. The manifold assembly of claim 14 wherein no plenum chamber precursor inlet is angled from any other plenum chamber precursor inlet.

16. The manifold assembly of claim 15 wherein the plenum chamber purge gas inlet is angled from the plenum chamber precursor inlets by from about 80° to 100°.

17. The manifold assembly of claim 15 wherein the plenum chamber purge gas inlet is angled from the plenum chamber precursor inlets by from about 89° to 91°.

18. The manifold assembly of claim 14 further comprising a valve in the respective precursor feed streams proximate the body.

19. The manifold assembly of claim 14 further comprising a 3-way valve in the respective precursor feed streams proximate the body.

20. The manifold assembly of claim 14 further comprising structure on the body configured to mount the body to a substrate processing chamber with the plenum chamber outlet proximate to and connected with a substrate processing chamber inlet.

21. The manifold assembly of claim 14 wherein the plenum chamber purge gas inlet is on the longitudinal axis.

22. A reactive precursor feeding manifold assembly, comprising:
an elongate body comprising an elongate plenum chamber, the plenum chamber having a longitudinal axis;
a plurality of precursor feed streams on the body in fluid communication with the plenum chamber at respective precursor inlets to the plenum chamber received along the longitudinal axis;
a purge gas stream on the body in fluid communication with the plenum chamber at a purge gas inlet to the plenum chamber which is upstream of the plenum chamber precursor inlets;
the body comprising a plenum chamber outlet configured to connect with a substrate processing chamber, the plenum chamber outlet being substantially vertically opposed relative to the purge gas inlet; and
structure on the body configured to mount the body to a substrate processing chamber with the plenum chamber outlet proximate to and connected with a substrate processing chamber inlet, and with the longitudinal axis being substantially vertical.

23. The manifold assembly of claim 22 wherein the structure comprises a projection on the body.

24. The manifold assembly of claim 22 wherein the structure comprises a flange.

25. The manifold assembly of claim 22 wherein the plenum chamber purge gas inlet is on the longitudinal axis.

26. The manifold assembly of claim 22 further comprising a valve in the respective precursor feed streams proximate the body.

27. The manifold assembly of claim 22 further comprising a 3-way valve in the respective precursor feed streams proximate the body.
